(19) United States
(12) Patent Application Publication
(10) Pub. No.: US 2015/0179594 A1
(43) Pub. Date: Jun. 25, 2015

(54) PACKAGE SUBSTRATE AND METHOD FOR MANUFACTURING THE SAME

(71) Applicant: SAMSUNG ELECTRO-MECHANICS CO., LTD., Suwon-si (KR)

(72) Inventors: Jun-Oh HWANG, Suwon-si (KR); Myung-Sam KANG, Suwon-si (KR); Young-Kwan LEE, Suwon-si (KR); Seung-Yeop KOOK, Suwon-si (KR); Seung-Eun LEE, Suwon-si (KR); Se-Rang IM, Suwon-si (KR)

(73) Assignee: SAMSUNG ELECTRO-MECHANICS CO., LTD., Suwon-si (KR)

(21) Appl. No.: 14/219,740

(22) Filed: Mar. 19, 2014

(30) Foreign Application Priority Data
Dec. 24, 2013 (KR) 10-2013-0162584

(51) Int. Cl. H01L 23/00

(52) U.S. Cl. CPC H01L 24/06; H01L 24/03; H01L 2224/036; H01L 2224/03002; H01L 2224/0312

(57) ABSTRACT

A package substrate and a method for manufacturing the same are disclosed. The method for manufacturing a package substrate in accordance with an aspect of the present invention includes: forming a first open hole corresponding to a shape of a bonding pad in a first photo resist; laminating a second photo resist on the first photo resist and forming a second open hole corresponding to shapes of a soldering pad, a circuit pattern layer and the bonding pad in the second photo resist; and forming a pattern plating layer up to a predetermined height in the first open hole and the second open hole.

### CROSS-REFERENCE TO RELATED APPLICATIONS

This application claims the benefit of Korean Patent Application No. 10-2013-0162584, filed with the Korean Intellectual Property Office on Dec. 24, 2013, the disclosure of which is incorporated herein by reference in its entirety.

### BACKGROUND

1. Technical Field

The present invention relates to a package substrate and a method for manufacturing the same.

2. Background Art

New forms and various types of package substrates, which are mainly used for substrates for memory package, have been constantly developed in order to cope with the demands for smaller, faster and more functional electronic devices.

Particularly, making the package substrates smaller and thinner has been an important task, and there have been a number of studies for packaging a larger capacity memory in higher integration.

However, while the wire bonding pitch for the conventional package substrate has been constantly decreasing, there have been difficulties in providing a sufficient pad width for stably supporting the wire bonding due to the shortcomings of the circuit technologies.

Moreover, manufacturing the conventional package substrate requires complicated processes, such as several pattern plating processes.

The related art of the present invention is disclosed in Korea Patent Publication No. 2001-0056778 (laid open on Jul. 4, 2001).

### SUMMARY

The present invention provides a method for manufacturing a package substrate that can simplify manufacturing processes by minimizing the number of pattern plating and can provide a width of a bonding pad more efficiently.

An aspect of the present invention features a method for manufacturing a package substrate that includes: forming a first open hole corresponding to a shape of a bonding pad in a first photo resist; laminating a second photo resist on the first photo resist and forming a second open hole corresponding to shapes of a soldering pad, a circuit pattern layer and the bonding pad in the second photo resist; and forming a pattern plating layer up to a predetermined height in the first open hole and the second open hole.

The method can also include forming an electroless plating layer on the first photo resist and the first open hole, between the forming of the first open hole and the forming of the second open hole.

After the forming of the pattern plating layer, the method can also include: removing the second photo resist and the electroless plating layer that is exposed; laminating a solder resist on the first photo resist and the pattern plating layer; and exposing the soldering pad by forming a soldering hole corresponding to the shape of the soldering pad in the solder resist.

The method can also include forming a silver plating layer and a nickel plating layer successively in the first open hole, between the forming of the first open hole and the forming of the electroless plating layer. The electroless plating layer and the pattern plating layer can be made of a copper plating layer.

The second photo resist can be made of a dry film.

Another aspect of the present invention features a package substrate that includes: a soldering pad covered by a solder resist in such a way that a bottom surface thereof is exposed through a soldering hole formed in the solder resist; a circuit pattern layer formed on a same plane as the soldering pad to have one end thereof coupled with the soldering pad, and covered by the solder resist; and a bonding pad formed on a plane that is higher than the soldering pad and the circuit pattern layer to be coupled with the other end of the circuit pattern layer, and covered by a first photo resist in such a way that an upper surface thereof is exposed.

The soldering pad, the circuit pattern layer and the bonding pad can be formed in an integrated fashion and coupled with one another without a via.

### BRIEF DESCRIPTION OF THE DRAWINGS

FIG. 1 is a flow diagram showing a method for manufacturing a package substrate in accordance with an embodiment of the present invention.

FIGS. 2 to 9 show each respective step of the method for manufacturing a package substrate in accordance with an embodiment of the present invention.

FIG. 10 is a cross-sectional view showing a package substrate in accordance with an embodiment of the present invention.

FIG. 11 shows a soldering pad, a circuit pattern layer and a bonding pad in the package substrate in accordance with an embodiment of the present invention.

### DETAILED DESCRIPTION

Hereinafter, a package substrate and a method for manufacturing the same in accordance with certain embodiments of the present invention will be described in detail with reference to the accompanying drawings. In describing the present invention with reference to the accompanying drawings, any identical or corresponding elements will be assigned with same reference numerals, and no redundant description thereof will be provided.

Terms such as “first” and “second” can be used in merely distinguishing one element from another identical or corresponding element, but the above elements shall not be restricted to the above terms.

When one element is described to be “coupled” to another element, it does not refer to a physical, direct contact between these elements only, but it shall also include the possibility of yet another element being interposed between these elements and each of these elements being in contact with said yet another element.

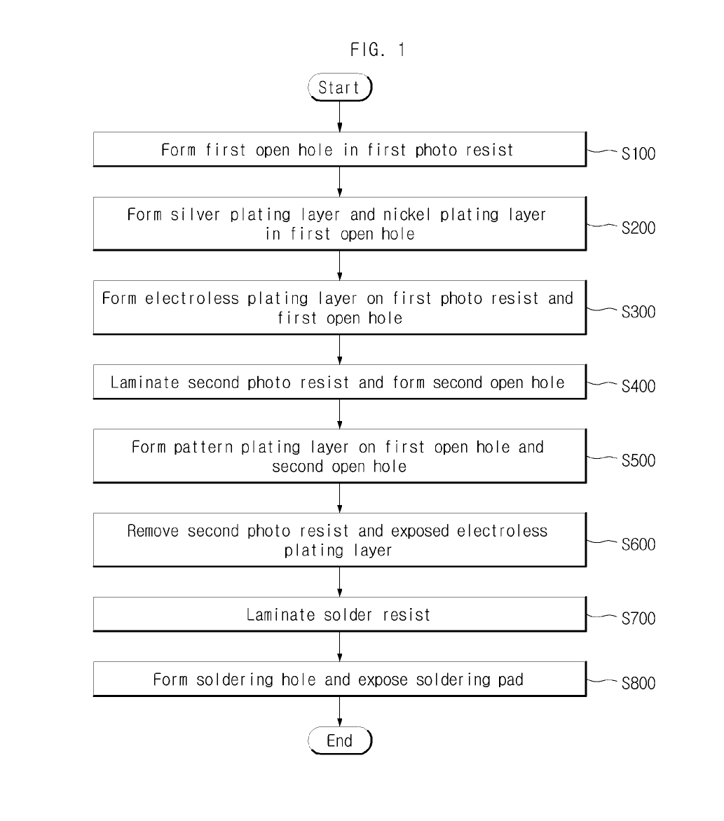

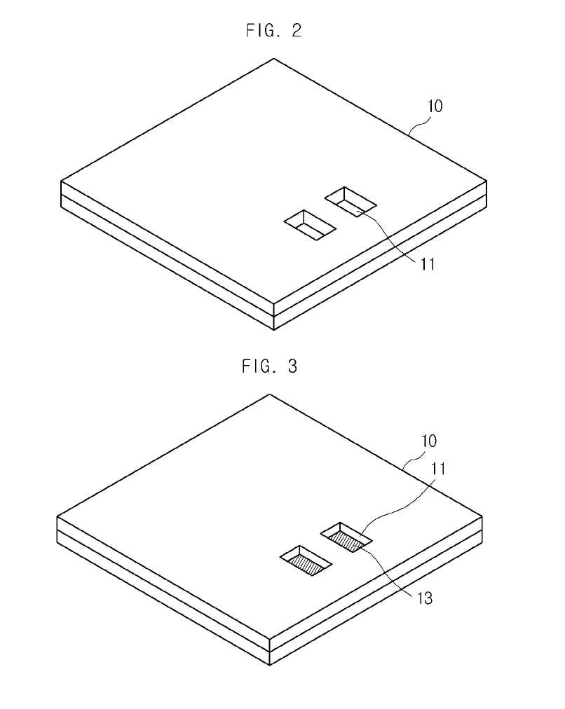

FIG. 1 is a flow diagram showing a method for manufacturing a package substrate in accordance with an embodiment of the present invention. FIGS. 2 to 9 show each respective step of the method for manufacturing a package substrate in accordance with an embodiment of the present invention.

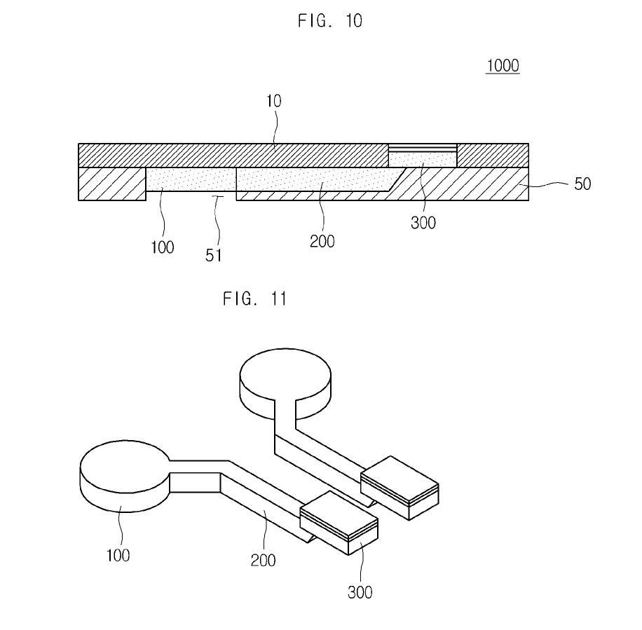

As shown in FIGS. 1 to 9, the method for manufacturing a package substrate in accordance with an embodiment of the present invention starts with forming a first open hole 11 corresponding to a shape of a bonding pad 300 (see FIG. 10) in a first photo resist 10 (S100; see FIG. 2).

Here, the first photo resist 10 is a material such as PID (Photo Imageable Dielectric), of which a portion irradiated by light is dissolved or undissolved by a developer, and can have the first open hole 11 formed therein through exposure and developing processes, as shown in FIG. 2.

The bonding pad 300 is a portion of a package substrate 1000 (see FIG. 10) that is connected with a separate semiconductor chip through, for example, wire bonding and can be provided at various locations and in various numbers as necessary.

Meanwhile, the step of S100 can be performed while the first photo resist 10 is laminated on a separate carrier, as shown in FIG. 2.

Thereafter, a second photo resist 30 can be laminated on the first photo resist 10, and a second open hole 31, corresponding to shapes of a soldering pad 100 (see FIG. 100), a circuit pattern layer 200 (see FIG. 10) and the bonding pad 300, can be formed in the second photo resist 30 (S400; see FIG. 5).

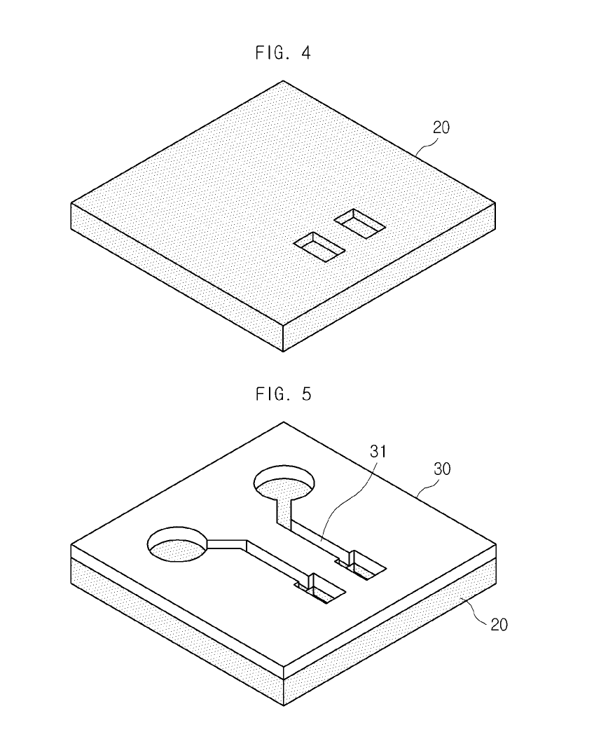

Here, the second photo resist 30 is also a material of which a portion irradiated by light is dissolved or undissolved by a developer, and can have the second open hole 31 formed therein through exposure and developing processes, as shown in FIG. 4.

Moreover, the soldering pad 100 is a portion that is connected with a separate solder ball, and the circuit pattern layer 200 is a portion that is electrically connected with the soldering pad 100 and the bonding pad 300. The soldering pad 100 and the circuit pattern layer 200 can be also provided at various locations and in various numbers as necessary.

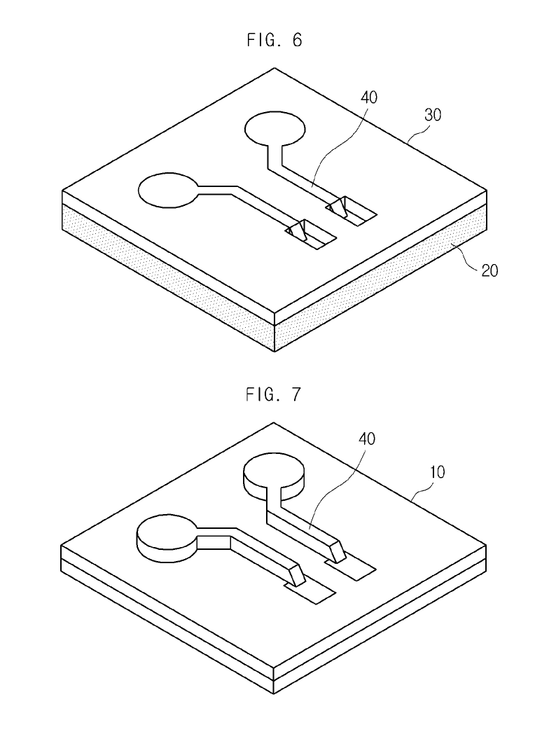

Then, a pattern plating layer 40 can be formed up to a predetermined height in the first open hole 11 and the second open hole 31 (S500; see FIG. 6). Here, “pattern plating” refers to selectively plating a portion corresponding to a conductive pattern in a process of fabricating a package substrate, and the pattern plating layer 40 can be formed inside the first open hole 11 and the second open hole 31 through pattern plating.

As such, the method for manufacturing a package substrate in accordance with the present embodiment can form the soldering pad 100, the circuit pattern layer 200 and the bonding pad 300 through a single pattern plating process and thus can minimize the number of pattern plating and simplify the manufacturing process of the package substrate 1000.

Moreover, since the bonding pad 300 is embedded in the first photo resist 10, it is possible to prevent a loss of width of the bonding pad 300 during, for example, a flash etching process for removing the above-described carrier, and thus the width of the bonding pad 300 can be provided more efficiently.

The method for manufacturing a package substrate in accordance with the present embodiment can further include forming an electroless plating layer 20 on the first photo resist 10 and the first open hole 11 (S300; see FIG. 4), in between the steps of S100 and S400.

Here, “electroless plating” reduces metal ions in aqueous solution of metal salt autocatalytically by force of reducing agent only, without having electric energy supplied thereto from an outside, and precipitates metal on surfaces of the first photo resist 10 and the first open hole 11. Accordingly, a seed for performing the above-described pattern plating can be formed through the step of S300.

Moreover, since the electroless plating layer 20 is interposed between the first photo resist layer 10 and the second photo resist layer 30, it is possible to prevent the first photo resist 30 from being damaged while forming the second open hole 31 in the second photo resist 30 or removing the second photo resist 30.
The method for manufacturing a package substrate in accordance with the present embodiment can further include removing the second photo resist 30 and the exposed electroless plating layer 20 (S600; see FIG. 7), after the step of S500.

The electroless plating layer 20 exposed due to no pattern plated thereon and the second photo resist 30 are both used in the fabrication process of the package substrate 1000 but are functionally unnecessary and thus can be removed after the step of S500.

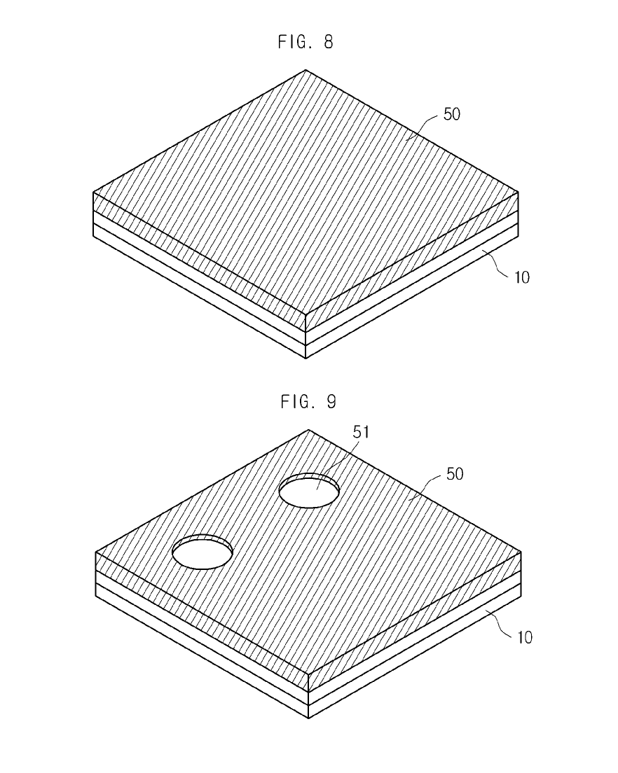

Next, a solder resist 50 can be laminated on the first photo resist 10 and the pattern plating layer 40 (S700; see FIG. 8). Here, the solder resist 50 is, for example, a coating material used for protecting a portion that does not require soldering or solder coating and can be coated over the first photo resist 10 and the pattern plating layer 40 in a predetermined thickness.

Then, a soldering hole 51 corresponding to the soldering pad 100 can be formed in the solder resist 50 to expose the soldering pad 100 (S800; see FIG. 9). Here, the soldering hole 51 can be formed in the solder resist 50 through exposure and developing processes, as shown in FIG. 9.

Accordingly, when a separate soldering ball is joined to the soldering pad 100, the solder resist 50 around the soldering hole 51 can function as a dam to disperse a load exerted to a portion where the soldering ball is joined, thereby improving the reliability of the portion where the soldering ball is joined.

The method for manufacturing a package substrate in accordance with the present embodiment can further include forming a silver plating layer and a nickel plating layer 13 successively in the first open hole 11 (S200) in between the steps of S100 and S300, and the electroless plating layer 20 and the pattern plating layer 40 can be made of a copper plating layer.

Generally, since the copper plating layer used as a pattern plating layer is exposed and thus may suffer with, for example, corrosion, the uppermost portion of the bonding pad 300 is formed with a silver plating layer, and a nickel plating layer is formed below the silver plating layer, making it possible to facilitate the joining between the silver plating layer and the copper plating layer.

Therefore, the method for manufacturing a package substrate in accordance with the present embodiment introduces the step of S200 to successively fill in the silver plating layer and the nickel plating layer 13 in the first open hole 11 so as to readily form the above-described structure of bonding pad 300.

In the method for manufacturing a package substrate in accordance with the present embodiment, the second photo resist 30 can be made of a dry film. Here, the dry film is a filmed photo resist and can form the second open hole 31 through exposure and developing processes.

Moreover, as the second photo resist 30 is formed with the dry film, the second photo resist 30 can be readily removed in the step of S600 by peeling off the dry film from the first photo resist 10.

FIG. 10 is a cross-sectional view showing the package substrate in accordance with an embodiment of the present invention. FIG. 11 shows the soldering pad, the circuit pattern layer and the bonding pad in the package substrate in accordance with an embodiment of the present invention.

As illustrated in FIGS. 10 and 11, the package substrate 1000 in accordance with an embodiment of the present invention includes the soldering pad 100, the circuit pattern layer 200 and the bonding pad 300.

The soldering pad 100 is a portion covered by the solder resist 50 in such a way that a bottom surface thereof is exposed through the soldering hole 51 formed in the solder resist 50 and can be connected with, for example, a separate solder ball.

The circuit pattern layer 200 is formed on a same plane as the soldering pad 100 to have one end thereof coupled with the soldering pad 100 and is covered by the solder resist 50, and can electrically connect the soldering pad 100 with the bonding pad 300.

The bonding pad 300 is formed on a plane that is higher than the soldering pad 100 and the circuit pattern layer 200 to be coupled with the other end of the circuit pattern layer 200 and is covered by the first photo resist 10 in such a way that an upper surface thereof is exposed, and can be connected with, for example, a separate semiconductor chip through wire bonding.

If the circuit pattern layer 200 were formed on a same plane as the bonding pad 300, the layer formed with the bonding pad 300 might not be flat, depending on the shape of the circuit pattern layer 200, and thus defect might be resulted from air bubbles entered in, for example, an adhesive film when the separate semiconductor chip is coupled with the bonding pad 300.

Accordingly, the package substrate 1000 in accordance with an embodiment of the present invention can prevent the above-described defect by having the circuit pattern layer 200 formed on the same plane as the soldering pad 200 and on a different plane from the bonding pad 300, making it possible to further improve the reliability.

Moreover, since the bonding pad 300 is embedded in the first photo resist 10, it is possible to prevent a loss of width of the bonding pad 300 during, for example, a flash etching process, and thus the width of the bonding pad 300 can be provided more efficiently.

Moreover, when a separate soldering ball is joined to the soldering pad 100, the solder resist 50 around the soldering hole 51 can function as a dam to disperse a load exerted to a portion where the soldering ball is joined, thereby improving the reliability of the portion where the soldering ball is joined.

The package substrate 1000 in accordance with the present embodiment can have the soldering pad 100, the circuit pattern layer 200 and the bonding pad 300 formed in an integrated fashion and coupled to one another without a via. That is, as illustrated in FIG. 11, the soldering pad 100, the circuit pattern layer 200 and the bonding pad 300 can be integrated together and thus can be electrically connected with one another without a separate via structure.

Accordingly, since processes for forming a via can be omitted when fabricating the package substrate 1000 in accordance with the present embodiment, the manufacturing process can be further simplified.

The configurations and fabrication processes of the package substrate 1000 in accordance with the present embodiment have been described above with reference to the method for manufacturing a package substrate in accordance with an embodiment of the present invention and thus will not be described redundantly herein.

Although a certain embodiment of the present invention has been described hitherto, it shall be appreciated that the present invention can be variously modified and permutated by those of ordinary skill in the art to which the present invention pertains by supplementing, modifying, deleting and/or adding an element without departing from the technical ideas of the present invention, which shall be defined by the claims appended below. It shall be also appreciated that such modification and/or permutation are also included in the claimed scope of the present invention.

1. A method for manufacturing a package substrate, comprising:
forming a first open hole corresponding to a shape of a bonding pad in a first photo resist;
laminating a second photo resist on the first photo resist and forming a second open hole corresponding to shapes of a soldering pad, a circuit pattern layer and the bonding pad in the second photo resist; and
forming a pattern plating layer up to a predetermined height in the first open hole and the second open hole.

2. The method of claim 1, further comprising, between the forming of the first open hole and the forming of the second open hole:
forming an electroless plating layer on the first photo resist and the first open hole.

3. The method of claim 2, further comprising, after the forming of the pattern plating layer:
removing the second photo resist and the electroless plating layer that is exposed;
laminating a solder resist on the first photo resist and the pattern plating layer; and
exposing the soldering pad by forming a soldering hole corresponding to the shape of the soldering pad in the solder resist.

4. The method of claim 2, further comprising, between the forming of the first open hole and the forming of the electroless plating layer:
forming a silver plating layer and a nickel plating layer successively in the first open hole,
wherein the electroless plating layer and the pattern plating layer are made of a copper plating layer.

5. The method of claim 1, wherein the second photo resist is made of a dry film.

6. A package substrate, comprising:
a soldering pad covered by a solder resist in such a way that a bottom surface thereof is exposed through a soldering hole formed in the solder resist;
a circuit pattern layer formed on a same plane as the soldering pad to have one end thereof coupled with the soldering pad, and covered by the solder resist; and
a bonding pad formed on a plane that is higher than the soldering pad and the circuit pattern layer to be coupled with the other end of the circuit pattern layer, and covered by a first photo resist in such a way that an upper surface thereof is exposed.

7. The package substrate of claim 6, wherein the soldering pad, the circuit pattern layer and the bonding pad are formed in an integrated fashion and are coupled with one another without a via.

8. The method of claim 2, wherein the second photo resist is made of a dry film.

9. The method of any of claim 3, wherein the second photo resist is made of a dry film.

10. The method of claim 4, wherein the second photo resist is made of a dry film.
